(19) United States
(12) Patent Application Publication
(10) Pub. No.: US 2024/0349625 A1
(43) Pub. Date: Oct. 17, 2024

(54) ELECTRONIC SYSTEM WITH NON-VOLATILE WRITING BY ELECTRICAL CONTROL AND WITH READING BY HALL EFFECT

(71) Applicants: Commissariat à l'énergie atomique et aux énergies alternatives, Paris (FR); THALES, Courbevoie (FR); Centre national de la recherche scientifique, Paris (FR); UNIVERSITE GRENOBLE ALPES, Saint Martin D'Heres (FR)

(72) Inventors: Cécile GREZES, Grenoble (FR); Laurent VILA, Grenoble (FR); Jean-Philippe ATTANE, Grenoble (FR); Manuel BIBES, Palaiseau (FR)

(73) Assignees: Commissariat à l'énergie atomique et aux énergies alternatives, Paris (FR); THALES, Courbevoie (FR); Centre national de la recherche scientifique, Paris (FR); UNIVERSITE GRENOBLE ALPES, Saint Martin D'Heres (FR)

(21) Appl. No.: 18/294,439

(22) PCT Filed: Aug. 3, 2022
(86) PCT No.: PCT/EP2022/071817

§ 371 Date: Feb. 1, 2024

(30) Foreign Application Priority Data
Aug. 6, 2021 (FR) FR2108564

(51) Int. Cl. H10N 52/00; G11C 11/16; H10N 50/10; H10N 50/20

(52) U.S. Cl. CPC H10N 52/101; G11C 11/161; G11C 11/1673; G11C 11/1675; H10N 50/10; H10N 50/20

(57) ABSTRACT

An electronic system includes an electronic device having a stack of layers, the stack including a first electrode, a subassembly with electrically controllable remanent states, a two-dimensional electron gas, a magnetic subassembly comprising at least one magnetic layer, and a second electrode having two first contacts and a second contact. The system also includes a writing device writing remanent states by applying an electric field between the two electrodes, and a Hall-effect reading device reading the remanent state by applying a current between the two first contacts and by measuring the voltage between the second contact and a reference potential.

The present invention relates to an electronic system with non-volatile writing by electrical control and with reading by Hall effect.

The present invention relates to the field of microelectronics and in particular to the field of memory devices, logic devices, neuromorphic devices based on non-volatile electrically controlled dielectrics, in particular for information and communication technologies. Dielectric materials with non-volatile electrical control are characterized by a non-linear relation between the applied voltage and the apparent stored charge following a hysteresis cycle. The remanent states of the hysteresis cycle can be used to store information in a non-volatile way.

Ferroelectric materials are examples of such materials with remanent states. In fact, ferroelectric materials have a spontaneous macroscopic polarization, which can be written by applying a voltage. It is possible to encode a piece of information in the ferroelectric state, which has led to the emergence of memory devices/ferroelectric logic devices.

An example of a known device using such effect is the Ferroelectric Random Access Memory (Fe-RAM). The Fe-RAM is a memory device similar to a Dynamic Random Access Memory (DRAM) to which a ferroelectric layer is added in order to obtain a property of non-volatility. The advantage of the Fe-RAM is to combine the speed of the random-access memory and the non-volatile features of the flash memory.

In the case of a Fe-RAM, the writing of information to be stored is performed by applying a voltage between the two faces of the ferroelectric layer. The information is thereby encoded in the polarization state of the ferroelectric layer.

The reading is performed by applying a voltage and by measuring the current produced. More precisely, a voltage pulse is applied between the two faces of the ferroelectric layer in order to attempt to switch the polarization from a first state to a second state, e.g. from the state “0” to the state “1”. If the Fe-RAM was already in the state “1”, the only output current read is related to the applied voltage pulse. If the Fe-RAM was initially in the state “0”, the current produced will be the sum between the current related to the voltage pulse and the depolarization current, related to the reversal of the polarization.

The read mechanism is thus destructive: The read erases the stored memory state, which involves rewriting the Fe-RAM by means of a particular architecture.

A second example of a known device using the properties of ferroelectric materials is the Ferroelectric Field Effect Transistor (Fe-FET). Field effect transistors are unipolar 3-terminal devices based on the action of an electric field on the conductivity of a channel connecting the source to the drain. In order to achieve non-volatility, the Fe-FET uses a ferroelectric element inserted between the gate electrode and the channel.

In the case of a Fe-FET, the information is encoded in the polarization of the ferroelectric material that acts as a non-volatile gate, controlling the conductivity of the channel of the transistor. The polarization state is read by measuring the longitudinal resistance of the channel (parallel to the read current) with a voltage lower than the coercive voltage of the ferroelectric material. The memory is not erased.

The mechanism of reading is certainly non-destructive but suffers from errors of reading due to the partial depolarization induced by the application of the read voltage on the ferroelectric material, and the requirements imposed on the choice of materials limit the endurance of the devices.

Resistive Random Access Memories (Re-RAM) are another example of a device using the non-volatile electrical control on the resistance in a dielectric material.

In the case of Re-RAMs, an electric field is applied in order to force the dielectric material, which is normally insulating, to be conductive through a conduction channel. Such conduction is obtained by different mechanisms including charge trapping, ion migration or the formation of conductive filaments. The information is then encoded in the remanent resistance states of the conduction channel of the dielectric element.

The reading is done by measuring the resistance of the dielectric with a voltage lower than the write voltage at the terminals of the dielectric.

Since reading does not eliminate the coding of the information, the mechanism of reading is in principle non-destructive but suffers from errors of reading due to the effect of the read voltage on the dielectric material, and involves the application of high voltages.

A known alternative to Re-RAM memory is to use a Phase Changing Random Access Memory (PC-RAM). The material used is then a phase-change material, which under the application of an electric current will switch between an amorphous phase that is not very conductive and a crystalline phase that is conductive.

Nevertheless, such a material involves a displacement of material in operation, so that such a component has an endurance problem. PC-RAMs also involve high working voltages.

There is thus a need for a non-volatile electronic system overcoming the aforementioned drawbacks.

To this end, the description describes an electronic system with non-volatile writing by electrical control and with reading by Hall effect comprising an electronic device including a stack of layers stacked along a direction of stacking, the stack of layers. The stack of layers comprises a first electrode, a remanent subassembly comprising at least one dielectric layer such that said remanent subassembly has at least two remanent states which can be electrically controlled, a two-dimensional electron gas, a magnetic subassembly comprising at least one magnetic layer, and a second electrode comprising two first contacts each extending along a first direction and a second contact extending along a second direction, the second direction being distinct from the first direction, the first and the second directions being in a plane perpendicular to the direction of the stack. The electronic system includes a writing device suitable for writing remanent states of the remanent-state subassembly by applying an electric field between the first electrode and the second electrode by modulating the electrical resistance of the two-dimensional electron gas, and a Hall-effect reading device suitable for reading the remanent state of the remanent-state subassembly by applying a current between the first two contacts and by measuring the voltage between the second contact and a reference potential.

Unlike the prior art corresponding to magnetic memory devices, the mechanism of writing of the electronic system does not reverse the magnetization of the remanent-state subassembly when an electric field is applied between the first electrode and the second electrode. The writing device of the electronic system serves to change the remanent state corresponding to a modulation of the electrical resistance of the two-dimensional electron gas. An improved writing results therefrom.

According to other particular embodiments, the electronic system has one or a plurality of the following features, taken individually or according to all technically possible combinations:
the first electrode includes at least one contact, the writing device applying the electric field between the at least one contact of the first electrode and at least one contact of the second electrode.
the first electrode is in contact with the remanent-state subassembly.
the first electrode is merged with the remanent-state subassembly.
the second electrode is in contact with the two-dimensional electron gas.
the second electrode is merged with the two-dimensional electron gas.
the second electrode is in contact with the magnetic subassembly.
the second electrode is merged with the magnetic subassembly.
the second electrode includes at least one additional contact, the reference potential being the potential of the additional contact.
the electrically controllable remanent states of the remanent state subassembly can be controlled by a ferroelectric effect, a trapped charge effect, an ion migration effect or a combination of said effects.
the two-dimensional electron gas has a carrier density greater than 10¹⁰ cm⁻².
the magnetic subassembly comprises at least one ferromagnetic element selected from a ferromagnetic metal alloy, a ferromagnetic oxide, a magnetic semiconductor, a ferromagnetic composite element with a plurality of ferromagnetic and metallic layers, a Heusler alloy, a rare earth alloy or a combination of such materials.
the magnetic subassembly comprises at least one ferrimagnetic element selected from a ferrimagnetic metal alloy, a ferrimagnetic oxide, a composite ferrimagnetic element with a plurality of ferromagnetic or ferrimagnetic and metallic layers, or a rare earth ferrimagnetic alloy, or a combination of such materials.
the magnetic subassembly comprises at least one antiferromagnetic element selected from an antiferromagnetic metal alloy, an antiferromagnetic oxide, a composite antiferromagnetic element having a plurality of magnetic and metallic layers antiferromagnetically coupled to each other, or a combination of such materials.
the stack of layers extends between two ends, one end being the first electrode and the other end being the second electrode.
the magnetic subassembly comprises at least one magnetic element selected from a material having an extraordinary Hall effect greater than 0.5% and a material having a magnetoresistance greater than 0.5%.
the stack of layers further includes at least one interfacing layer, the interfacing layer including at least one layer selected from a non-magnetic metallic layer and a layer displaying a spin-orbit effect.
the interfacing layer includes at least one element amongst a metal, a Weyl semi-metal, a two-dimensional material, a transition metal dichalcogenide and a topological insulator.
the electronic system includes at least one other electronic device (12), all the electronic devices being arranged in cascade or in the form of an array, each other electronic device including a stack of layers stacked along the direction of stacking.
the first electrode of an electronic device is connected to a second electrode of an adjacent electrical device.
one of the contacts of the second electrode of an electronic device is connected to one of the contacts of the second electrode of an adjacent electronic device.

The features and advantages of the invention will appear upon reading the following description, given only as an example, but not limited to, and making reference to the enclosed drawings, wherein:

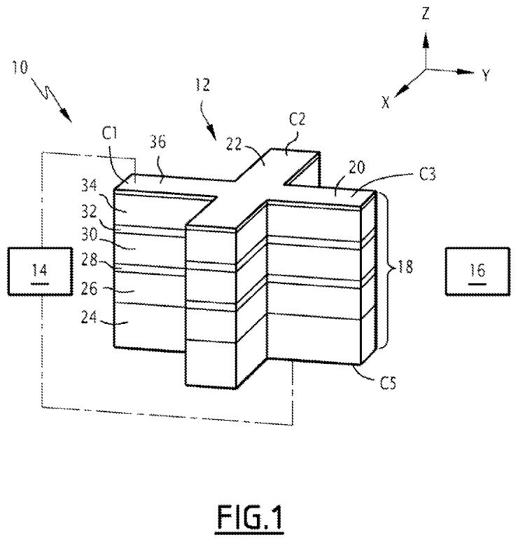

FIG. 1 is a schematic representation of an example of an electronic system with non-volatile writing by electrical control and with reading by Hall effect comprising in particular a remanent-state subassembly having at least two electrically controllable remanent states, a two-dimensional electron gas and a magnetic subassembly,

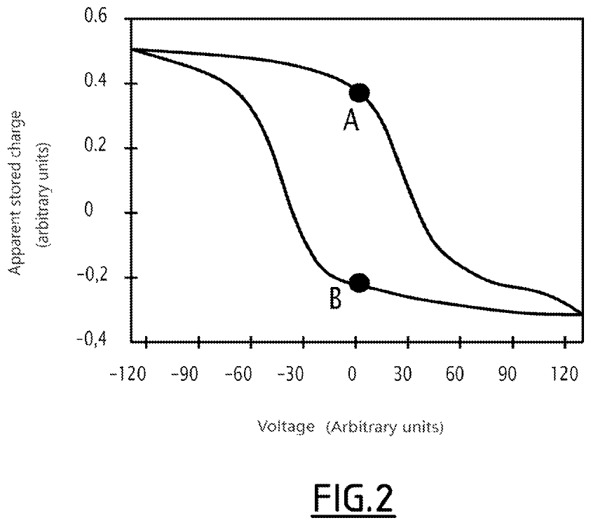

FIG. 2 is a schematic representation of a charge-voltage hysteresis cycle of a remanent-state subassembly,

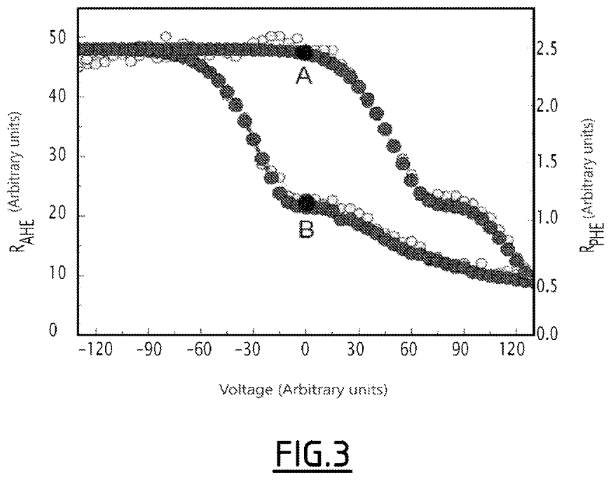

FIG. 3 is a schematic representation of the voltage dependence of the extraordinary and planar Hall effects in a ferromagnetic subassembly,

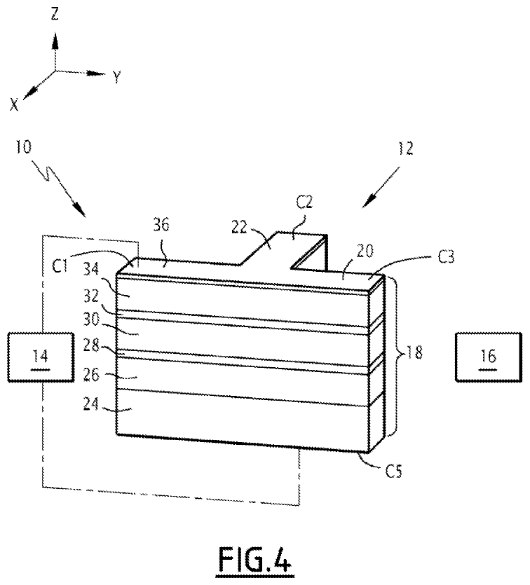

FIG. 4 is a schematic representation of another example of an electronic system with non-volatile writing by electrical control and with reading by Hall effect,

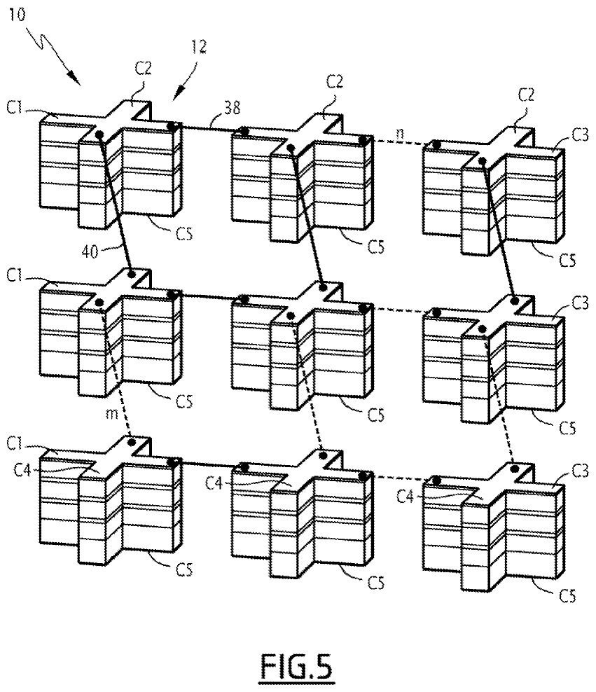

FIG. 5 is a schematic representation of an example of a system formed by cascade nesting of non-volatile electronic devices, and

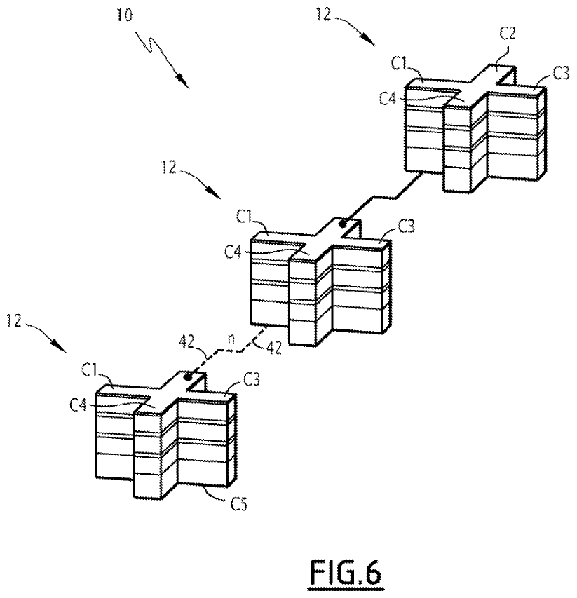

FIG. 6 is a schematic representation of an example of a system by array nesting of non-volatile electronic devices.

The electronic system with non-volatile writing by electrical control and with reading by Hall effect 10 is illustrated in FIG. 1. Hereinafter, such a system is simply called an electronic system.

The electronic system 10 includes an electronic device 12, a writing device 14 and a Hall-effect reading device 16.

The electronic system 10 is e.g. a memory, a logic device or a neuromorphic device.

In the present case, it can already be noted that the electronic system 10 has the specificity of being a system with electrical control and reading by the Hall effect.

As a recall, a Hall effect corresponds to the generation of an electric field and hence of a voltage perpendicular to an electric current flowing through a material.

For example, the so-called classical Hall effect, which occurs when a magnetic field is applied, generates a voltage perpendicular to the magnetic field and to the current.

According to another example, the so-called abnormal or extraordinary Hall effect, which occurs when the material carries a magnetization, generates a voltage perpendicular to the magnetization and to the current.

According to yet another example, the planar Hall effect, which occurs when the material carries a magnetization in the plane of the layer, generates a voltage in the plane of the layer and perpendicular to the current.

According to the example shown in FIG. 1, the electronic device 12 includes a stack of layers 18.

The layers of the stack 18 are layers stacked along a direction of stacking Z.

Two longitudinal directions are then defined which are perpendicular to the direction of stacking Z, a first longitudinal direction X and a second longitudinal direction Y. The two longitudinal directions X and Y are orthogonal to each other and chosen so that the axis of reference X, Y and Z is direct.

In a variant, the first longitudinal direction X and the second longitudinal direction Y are simply distinct and are not orthogonal to each other.

With reference to FIG. 1, the relative notions of bottom and top with respect to the direction of stacking Z, are also defined. A layer is lower than another layer if same is lower in the representation on the sheet in FIG. 1.

Finally, the thickness of a layer is defined as the dimension along the direction of stacking Z of the layer, i.e. the distance between the two faces thereof.

According to the example shown in FIG. 1, the stack 18 is a stack of superposed layers in the form of a cross.

Other shapes are possible, as will be subsequently described with reference to FIG. 4.

In the example described, the cross is formed by the joining of two branches 20 and 22, a first branch 20 being along the first longitudinal direction X and the second branch 22 being along the second longitudinal direction Y.

For the case shown in FIG. 1, from the bottom upwards, the electronic device 12 includes a first electrode 24, a remanent-state subassembly 26, a first interfacing layer 28, a two-dimensional electron gas 30, a second interfacing layer 32, a magnetic subassembly 34 and a second electrode 36.

Such order of the layers is not limiting and other possible orders will be subsequently described.

In the example described, the first electrode 24 includes a contact and the second electrode 36 includes four contacts, so that the electronic device 12 includes five contacts.

Also, hereinafter, the contacts of the second electrode 36 are called the first contact C1, the second contact C2, the third contact C3, the fourth contact C4, respectively, and the contact of the first electrode 24 is called the fifth contact C5.

Each contact C1, C2, C3, C4 and C5 is an electrical contact.

In the representation of FIG. 1, each contact C1, C2, C3, C4 is represented in the form of a parallelepiped extending along a main direction.

Although this shape is non-limiting, each contact C1, C2, C3, C4 has a respective main direction.

Furthermore, it should be noted that the contact for writing at the second electrode 36 can be anywhere on the electrode. The contact be made by one of the aforementioned contacts C1, C2, C3, C4, or by a specific contact which can be e.g. at the center of the cross formed by the second electrode 36.

According to the example of FIG. 1, the first electrode 24 is electrically connected via the contact C5. It should be noted that each electrode 24 or 36 can be made by conductive layers arranged on either side of the stack, but when one of the outer layers of the stack is conductive, the electrode 24 or 36 associated with the layer can be the outer layer as such.

According to the example described, the remanent-state subassembly 26 is positioned on the first electrode 24.

The expression “subassembly” refers herein to both a single layer and a set of layers.

In any case, whether a layer or a plurality of layers is concerned, the subassembly with remanent state 26 forms a non-volatile dielectric element with electrical control.

The dielectric element has a non-linear relation between the voltage V applied between the faces thereof and the apparent stored charge Q following a hysteresis cycle, resulting in at least two remanent states.

FIG. 2 graphically shows an example of such a relation by showing the hysteresis cycle Q-V characteristic of a non-volatile dielectric with electrical control. As can be seen in FIG. 2, the hysteresis cycle includes two remanent states denoted by A and B.

Such a non-linear relationship can e.g. result from an electrical control using a ferroelectric effect, a trapped charge effect, an ion migration effect, or a combination of a plurality of such effects.

The use of the remanent state subassembly 26 makes it possible to electrically control in a non-volatile way, the conductivity of the two-dimensional electron gas 30.

In any case, the remanent-state subassembly 26 has said remanent states which can be electrically controlled and comprises at least one dielectric material.

According to a first example, the dielectric material is a perovskite structure of the type ABO₃ (where A and B are cations). Such a structure is an oxide perovskite structure.

Thereby, the dielectric material is e.g. made of BaTiO₃, PZT (i.e. PbZr₁₋ₓTiₓO₃ with x varying between 0 and 1), of PMN-PT (i.e. [1−x]Pb(Mg_{1/3}Nb_{2/3}) O₃-xPbTiO₃ with x varying between 0 and 1), of BiFeO₃ (doped, if appropriate, e.g. with a rare earth on the Bi site, or with Mn on the Fe site), SrTiO₃ (doped, if appropriate), of KTiO₃ (doped, if appropriate), of Pr_{0.7}Ca_{0.3}MnO₃ (doped, if appropriate) or of YMnO₃ (doped, if appropriate).

According to a second example, the dielectric material is (Hf₁₋ₓZrₓ)O₂ or (Hf₁₋ₓGaₓ)O₂ (x varying between 0 and 1) or the alloys thereof.

The dielectric material can also be poly(vinylidene fluoride).

In such a second example, the dielectric material does not have the perovskite structure, unlike in the first example.

According to a third example, the dielectric material is a ferroelectric semiconductor.

GeTe, BiTeI, BiAlO₃ and Bi₂WO₃, doped, if appropriate, are examples of such ferroelectric semiconductor materials.

According to a fourth example, the dielectric material is chosen amongst the following compounds: SiOₓNₓ, (Ta₂O₅)ₓ (Tio2)₁₋ₓ or (Nb₂O₅)ₓ(TiNb₂O₇)₁₋ₓ (x varying between 0 and 1).

According to a fifth example, the dielectric material is chosen amongst halide perovskite structures such as CsPbBr₃, MAPbI₃, or MAPbBr₃.

In each of the preceding examples, the existence of the remanent states comes from a ferroelectric effect, a trapped charge effect, an ion migration effect, or a combination of a plurality of such effects. In practice, the predominant effect depends on the deposition conditions of the dielectric layer. According to the example described, the coercive electric field of the dielectric element and the thickness thereof are sufficiently small for the writing device 14 to be apt to write the remanent states at voltages compatible with microelectronic technologies, i.e. voltages below 10 volts (<10 V). A thickness of less than 100 nm and advantageously less than 50 nm in the aforementioned materials makes it possible to obtain such properties. The remanent-state subassembly 26 is also resistant to cycling, typically apt to withstand at least 10⁴ cycles.

In some cases, it is favorable to use a specific substrate so as to modulate the non-volatile electrical control properties thereof.

The two-dimensional electron gas 30 is a confined electron gas that forms at an interface between two layers. The confinement is such that it can be considered that the gas is strictly two-dimensional.

The two-dimensional electron gas 30 can form at the interface between two layers of the stack 18.

The resistance of the two-dimensional electron gas 30 can be electrically modulated in a non-volatile way under the effect of the remanent-state subassembly 26, more precisely by choosing the remanent state of the remanent-state subassembly 26.

Preferentially, to improve the electrical modulation of the Hall effect, the two-dimensional electron gas has a high carrier density (typically greater than 10¹⁰ cm⁻²).

The magnetic subassembly 34 is suitable for generating a contribution to the Hall effect of the electronic device 12.

Depending on the case, it concerns an extraordinary Hall effect, a planar Hall effect or a generation of a dipole field. In the latter case, it is the action of the dipole field on the two-dimensional electron gas that contributes to the Hall effect.

The magnetic subassembly 34 comprises at least one magnetic layer.

For example, the magnetic subassembly 34 is made of one or a plurality of materials, and comprises at least one ferromagnetic, ferrimagnetic or antiferromagnetic element.

As a variant or in addition, the magnetic subassembly 34 further includes magnetization anchoring layers, i.e. layers intended to set the direction of magnetization.

According to a first case, the magnetic subassembly comprises a ferromagnetic material.

According to a first example, the ferromagnetic material is a ferromagnetic metal alloy composed of elements such as Co, Fe, B, Ni or Al.

According to a second example, the magnetic material is a ferromagnetic oxide.

According to a third example, the ferromagnetic material is a magnetic semiconductor.

According to a fourth example, the magnetic material is a composite ferromagnetic element of the type [FM/M]ₙ/FM, i.e. a stack of a plurality of ferromagnetic layers FM and metallic layers M coupled together.

The number n varies between 1 and 10.

The ferromagnetic materials FM are e.g. the materials of the first three examples.

The metallic materials M are chosen from Al, Ta, Ru, Pt, W, Ir, Mo, Ti, Y and Au.

According to a fifth example, the ferromagnetic material is a Heusler alloy. Cu₂MnAl, Cu₂MnIn, Cu₂MnSn, NfiMnAl, NfiMnIn, NfiMnSn, NfiMnSb, Ni₂MnGa Co₂MnAl, Co₂MnSi, Co₂MnGa, Co₂MnGe, Pd₂MnAl, Pd₂MnIn, Pd>MnSn, Pd>MnSb, Co₂FeSi, Co₂FeAl, Fe₂VAl, Mn₂VGa, Co₂FeGe, MnGa, or MnGaRu are examples of Heusler alloys.

According to a sixth example, the ferromagnetic material can be produced with alloys containing rare earths such as e.g. Nd, Sm, Eu, Gd, Tb, or Dy.

According to a second example, the magnetic subassembly 34 comprises at least one ferrimagnetic element, e.g. chosen from a ferrimagnetic metal alloy, a ferrimagnetic oxide, a composite ferrimagnetic element with a plurality of ferromagnetic or ferrimagnetic and metallic layers, a Heusler alloy or a rare earth ferrimagnetic alloy, or a combination of such materials.

According to a third example, the magnetic subassembly 34 comprises at least one antiferromagnetic element chosen e.g. from an antiferromagnetic metal alloy, an antiferromagnetic oxide, a composite antiferromagnetic element having a plurality of magnetic and metallic layers antiferromagnetically coupled to each other, or a combination of such materials.

The thickness of the magnetic subassembly 34 is small (typically less than 100 nm), so as to optimize the reading by the Hall effect of the Hall effect reading device 16.

Moreover, the choice of materials can vary depending on the nature of the Hall effect used by the Hall effect reading device 16.

In the case of a Hall effect reading device 16 using the extraordinary Hall effect, it is preferable to choose materials with perpendicular magnetization and advantageously with extraordinary Hall effect angles greater than 0.5%.

For a planar Hall effect, it is preferable to choose planar magnetization materials with an anisotropic magnetoresistance greater than 0.5%.

Finally, in the case of a normal Hall effect measurement, via the demagnetizing field created in the two-dimensional electron gas by the ferromagnetic subassembly, it is preferable to use a material with high magnetization, i.e. a material such that μ₀M_{S}>0.2 Tesla (T).

According to the example shown in FIG. 1, the electronic device 12 includes two additional layers which are the interfacing layers 28 and 32.

Depending on the position and/or composition thereof, each interfacing layer 28 and 32 performs one or a plurality of the following functions: protecting the two-dimensional electron gas 30, participating in the formation of the two-dimensional electron gas 30, improving the transport properties thereof, improving the electronic transport properties of the electronic device 12, and/or improving the electrical modulation of the Hall effect in order to facilitate reading by the Hall effect reading device 16.

Each interfacing layer 28 and 32 has a relatively small thickness, which is e.g. less than or equal to 10 nm.

As an example, the interfacing layer 28 or 32 is a layer consisting of an element of the columns 3d, 4d, 5d, 4f, 5f of the periodic table such as Al, Ta, Ru, Pt, W, Ir, Mo, Ti, Y, Au or a combination of said elements, such as PtW.

According to another example, the interfacing layer 28 or 32 is a layer made of a material with strong spin-orbit coupling.

A material with strong spin-orbit is a material for converting a charging current into a spin current.

For example, the material displaying a strong spin-orbit coupling is tantalum (β-Ta), BiSb, Ta, β-tungsten (β-W), W or Pt.

According to a second example, the material with strong spin-orbit coupling is Cu or Au doped with elements of the columns 3d, 4d, 5d, 4f, 5f of the periodic table, such as W, Ta, Bi, so as to obtain large spin-orbit effects, or a combination of elements 5d as PtW.

According to a third example, the material with strong spin-orbit coupling is a two-dimensional spin-orbit material.

As an example of a two-dimensional spin-orbit material, the following materials can be cited: graphene, BiSe₂, BiS₂, BiSeₓTe₂₋ₓ (x varying between 0 and 2), BiS, TiS, WS₂, MoS₂, the TiSe₂, VSe₂, MoSe₂, B₂S₃, Sb₂S, T_{0.75}S, Re₂S₇, LaCPS₂, LaOAsS₂, ScOBiS₂, GaOBiS₂, AlOBiS₂, LaOSbS₂, BiOBiS₂, YOBiS₂, InOBiS₂, LaOBiSe₂, TiOBiS₂, CeOBiS₂, PrOBiS₂, NdOBiS₂, LaOBiS₂, or SrFBiS₂.

If appropriate, the above-mentioned materials can be doped.

According to a fourth example, the material with strong spin-orbit coupling is a topological insulator. A topological insulator is a material with an insulator band structure and which has metallic surface states.

For example, the material with strong spin-orbit coupling is Bi₂SE₃, BiSbTe, SbTe₃, HgTe or α-Sn.

According to a fifth example, the material with strong spin-orbit coupling is a Weyl semi-metal.

In such a case, the material with strong spin-orbit coupling is e.g. TaAs, TaP, NbAs, NbP, Na₃Bi, Cd₃As₂, WTe₂ or MoTe₂.

Furthermore, an irradiation of the material can be carried out with ions, such as He ions or Ar ions.

According to a sixth example, the material of the spin-orbit layer is a transition metal dichalcogenide and preferentially a ROCh₂ dichalcogenide. Indeed, such a material displays a good Rashba effect.

In such a formula, “R” is e.g. chosen from amongst La, Ce, Pr, Nd, Sr, Sr, Ga, Al, or In whereas ‘Ch’ is chosen amongst S, Se or Te.

The second electrode 36 includes two branches 20 and 22 and four contacts, namely the first contact C1, the second contact C2, the third contact C3 and the fourth contact C4.

The branches 20 and 22 are in contact with or merged with either the two-dimensional electron gas 30 or with the magnetic subassembly 34.

The contacts C1, C2, C3 and C4 are opposed in pairs.

Thereby, in the example described, the second contact C2 and the fourth contact C4 form a pair of opposite contacts and each extend mainly along the same direction, namely the first longitudinal direction X. The first contact C1 and the third contact C3 form the other pair of opposite contacts and each extend mainly along the same direction, namely the second longitudinal direction Y.

The operation of the system is now described with reference to FIG. 3.

As explained with reference to FIG. 2, the remanent-state subassembly 26 includes two remanent states denoted by A and B.

In the write mode, the writing device 14 modifies the states by applying a voltage between the first electrode 24 and the second electrode 36.

According to the example described, as shown by the dotted lines in FIG. 1, the writing device 14 writes by applying a voltage between the first contact C1 and the fifth contact C5. Any contact of the second electrode 36 can be used herein.

As a result, the writing device 14 is, e.g, a transistor serving to charge, either positively or negatively, the second electrode 36.

The mechanism for reading the remanent states A or B by the Hall effect reading device 16 involves the Hall effect.

For this purpose, the Hall effect reading device 16 measures the difference of potential, i.e. the voltage produced by the Hall effect between the second contact C2 and the fourth contact C4 when a current is applied between the first contact C1 and the third contact C3.

In the absence of a fourth contact C4 (which can be seen in the embodiment described as an additional contact), the reference potential can be the potential of the third contact C3 or of any other contact even external to the system, e.g. the earth potential.

The reading by Hall effect is thus performed by measuring the Hall resistance of the magnetic sub-stack 34, perpendicular to the applied read current.

The Hall effect reading device 16 thereby includes a unit for injecting current and a unit for measuring the Hall voltage. As an example, the injection unit for current is a transistor distinct from the transistor of the writing device 14.

The graph in FIG. 3 clearly shows that it is possible to determine the two states by such measurement. In fact, the graph in FIG. 3 shows the dependence on applied voltage of the extraordinary (Anomalous) Hall Effect (AHE) and the Planar Hall effect (PHE) in the magnetic sub-stack 34, measured between the second contact C2 and the fourth contact C4 during the application of a current of 10 microamperes (HA) between the first contact C1 and the third contact C3.

Thereby, the reading by Hall effect is non-destructive, in the sense that the reading does not modify the state of the remanent-state subassembly 26.

As a result, the electronic system 10 combines in an original way, a two-dimensional electron gas 30 and a magnetic subassembly 34 for a reading by Hall effect, which is non-destructive and compatible with any type of non-volatile dielectric element with electrical control. Indeed, it is indifferent whether the dielectric element is based on a ferroelectric effect, a trapped charge effect, an ion migration effect, a filamentary formation effect or a combination of such effects.

The combination of the two-dimensional electron gas 30 and the magnetic subassembly 34 leads to an increase in the Hall effect serving a reliable, repeatable detection thereof.

As a result, better write and read performance for the 10 electronic system are obtained therefrom.

Furthermore, the manufacture of the electronic device 12 is relatively easy insofar as the assembly 18 can herein be lithographed and etched throughout the thickness.

Other embodiments having of the electronic system 10 are also conceivable.

According to a first example, the electronic device 12 has no interfacing layers or includes only one layer.

According to another variant, the device includes a stack 18 with layers arranged in a different order when the stack 18 is traversed from the bottom to the top.

By not considering the interfacing layers which may or may not be present in each of the embodiments which will now be described, the stack 18 shown in FIG. 1 presents, from the bottom upwards, the remanent-state subassembly 26, the two-dimensional gas layer 30 and the magnetic subassembly 34.

According to yet another example, the order is as follows: remanent-state subassembly 26, then magnetic subassembly 34, then two-dimensional gas layer 30.

Furthermore, depending on the case, the first electrode 24 can be positioned either at the top (as the upper electrode) or at the bottom (as the lower electrode). In the first case, the contacts C1 to C4 of the first electrode 24 are deposited last with respect to the other layers of the stack 18, whereas same are deposited first in the second case.

The operation and advantages described for the case of FIG. 1 remain unchanged for the embodiments with a different order of the main layers. Otherwise formulated, the order of the layers between the two electrodes 24 and 26 can be varied according to the needs, the two electrodes 24 and 26 being each time arranged at the ends of the stack 18.

Another embodiment of the device is illustrated in the FIG. 4.

In said example, the fourth contact C4 is removed.

The device then presents a stack of superposed layers in the shape of a “T” instead of the cross shape.

The Hall voltage is then read between the second contact C2 and an electrical reference potential.

The reference potential is e.g. the potential of the first contact C1 or of the third contact C3.

As a result, e.g. the density of devices 12 can be optimized.

It should be noted that, like in the case of FIG. 1, the order of the main layers can vary similarly and the interfacing layers 28 and 32 can either be present or not present.

With reference to FIGS. 5 and 6, it is also possible to envisage an electronic system 10 including a plurality of electronic devices 12.

The case of FIG. 5 corresponds to the case of electronic devices 12 connected together so as to form an array.

The array comprises n electronic devices 12 in a row and m electronic devices 12 in a column, m and n being integers, at least one of which is greater than or equal to 2.

In the example shown, the third contact C3 of an electronic device 12 of a line is connected to the first contact C1 of the adjacent electronic device 12 in the same row via a link 38.

As regards a column, the fourth contact C4 of an electronic device 12 is connected to the second contact C2 of the adjacent electronic device 12 in the same row via a link 40.

Such an arrangement is used for making the read current flow through a plurality of electronic devices and/or to sum the read voltages. The reading is thereby improved.

It should be noted that, like in the case of FIG. 1, the order of the main layers can vary in a similar way.

It should be noted that it is possible to remove, like in the case of FIG. 4, the fourth contact C4 on some or all of the electronic devices 12.

FIG. 6 corresponds to the case of electronic devices 12 arranged in cascade.

In such example, n electronic devices 12 are connected together one after the other.

More precisely, the fourth contact C4 of an electronic device 12 is connected to the fifth contact of a following electronic device 12 via a link 42.

Thereby, the connections between the electronic devices 12 are made in such a way that the Hall voltage produced by an electronic device 12 makes it possible to modify the state of the remanent-state sub-stack 26.

In this way in practice, it is possible to produce a cascade effect in the electronic system 10, which is advantageous for logical or neuromorphic applications.

Here again, like in FIG. 1, the order of the main layers can vary in a similar way.

1. An electronic system with non-volatile writing by electrical control and with reading by Hall effect, comprising:
an electronic device including a stack of layers stacked along a direction of stacking, the stack of layers comprising:
a first electrode,
a remanent-state subassembly comprising at least one dielectric layer such that said remanent-state subassembly has at least two remanent states which can be electrically controlled,
a two-dimensional electron gas with a resistance,
a magnetic subassembly comprising at least one magnetic layer, and
a second electrode including two first contacts each extending along a first direction and a second contact extending along a second direction, the second direction being distinct from the first direction, the first and second directions being in a plane perpendicular to the direction of the stack,
a writing device configured to write remanent states of the remanent-state subassembly by applying an electric field between the first electrode and the second electrode modulating the resistance of the two-dimensional electron gas, and
a Hall effect reading device configured to read the remanent state of the remanent-state subassembly by applying a current between the two first contacts and by measuring a voltage between the second contact and a reference potential.

2. The electronic system according to claim 1, wherein the first electrode has at least one contact, the writing device applying the electric field between the at least one contact of the first electrode and at least one contact of the second electrode.

3. The electronic system according to claim 1, wherein at least one of the following properties is verified:
the first electrode is in contact with the remanent-state subassembly,
the first electrode is merged with the remanent-state subassembly,
the second electrode is in contact with the two-dimensional electron gas,
the second electrode is merged with the two-dimensional electron gas,
the second electrode is in contact with the magnetic subassembly, and
the second electrode is merged with the magnetic subassembly.

4. The electronic system according to claim 1, wherein the second electrode includes at least an additional contact, the reference potential being the potential of the additional contact.

5. The electronic system according to claim 1, wherein the at least two remanent states of the remanent-state subassembly, which can be electrically controlled, can be controlled by a ferroelectric effect, a trapped charge effect, an ion migration effect or a combination of said effects.

6. The electronic system according to claim 1, wherein the two-dimensional electron gas has a carrier density greater than 10¹⁰ cm⁻².

7. The electronic system according to claim 1, wherein the magnetic subassembly comprises at least one ferromagnetic element chosen from a list consisting of a ferromagnetic metal alloy, a ferromagnetic oxide, a magnetic semiconductor, a composite ferromagnetic element having a plurality of ferromagnetic and metallic layers, a Heusler alloy, a rare earth alloy and a combination of such materials.

8. The electronic system according to claim 1, wherein the magnetic subassembly comprises at least one ferrimagnetic element chosen from a list consisting of a ferrimagnetic metal alloy, a ferrimagnetic oxide, a composite ferrimagnetic element having a plurality of ferromagnetic layers or ferrimagnetic and metallic layers, a rare earth ferrimagnetic alloy, and a combination of such materials.

9. The electronic system according to claim 1, wherein the magnetic subassembly comprises at least one antiferromagnetic element chosen from a list consisting of an antiferromagnetic metal alloy, an antiferromagnetic oxide, a composite antiferromagnetic element with a plurality of magnetic and metallic layers antiferromagnetically coupled to each other, and a combination of such materials.

10. The electronic system of claim 1, wherein the remanent-state subassembly is non-ferromagnetic and non-ferrimagnetic.

11. The electronic system according to claim 1, wherein the stack of layers extends between two ends, one end being the first electrode and the other end being the second electrode.

12. The electronic system according to claim 1, wherein the magnetic subassembly (34) comprises at least one magnetic element chosen from a list consisting of a material having an extraordinary Hall effect greater than 0.5% and a material having a magnetoresistance greater than 0.5%.

13. The electronic system according to claim 1, wherein the stack of layers further includes at least one interfacing layer, the interfacing layer including at least one layer selected from a non-magnetic metallic layer and a layer displaying a spin-orbit effect.

14. The device according to claim 13, wherein the interfacing subassembly includes at least one element chosen from a list consisting of a metal, a Weyl semi-metal, a two-dimensional material, a transition metal dichalcogenide and a topological insulator.

15. The electronic system according to claim 1, wherein the electronic system includes at least another electronic device, all of the electronic devices being arranged in cascade or in a form of an array, each other electronic device including a stack of layers stacked along the direction of stacking.

16. The electronic system according to claim 15, wherein the first electrode of the electronic device is connected to a second electrode of an adjacent electrical device.

17. The electronic system according to claim 16, wherein one of the contacts of the second electrode of the electronic device is connected to one of the contacts of the second electrode of an adjacent electronic device.
